(19) United States
(12) Patent Application Publication
(10) Pub. No.: US 2014/0211421 A1
(43) Pub. Date: Jul. 31, 2014

(54) Circuit Board Assembly

(71) Applicants: Matthew D. Mishrikey, Oakland, CA (US); James O'Keeffe, Newark, CA (US); Bruce R. Conway, La Honda, CA (US); Peter J. Dutton, Fremont, CA (US)

(72) Inventors: Matthew D. Mishrikey, Oakland, CA (US); James O'Keeffe, Newark, CA (US); Bruce R. Conway, La Honda, CA (US); Peter J. Dutton, Fremont, CA (US)

(73) Assignee: Tyco Electronics Corporation, Berwyn, PA (US)

(21) Appl. No.: 13/752,584

(22) Filed: Jan. 29, 2013

(51) Int. Cl. H05K 1/02

(52) U.S. Cl. CPC H05K 1/0203; H05K 1/0201
USPC 361/717; 361/721

(57) ABSTRACT

A circuit board assembly includes first and second circuit boards that each have a substrate and a conductive circuit layer positioned on the substrate. The first and second circuit boards are arranged such that the conductive circuit layers face each other across a gap. Thermal conductor pillars extend lengths across the gap between the conductive circuit layers of the first and second circuit boards. The thermal conductor pillars include opposite first and second ends that are engaged in thermal contact with the conductive circuit layers of the first and second circuit boards, respectively. The thermal conductor pillars provide thermal pathways for heat to travel between the first and second circuit boards.

### BACKGROUND OF THE INVENTION

The subject matter described and/or illustrated herein relates generally to circuit boards, and more particularly to circuit boards having electronic devices mounted thereto.

A wide variety of electronic devices are mounted on circuit boards, for example switches, relays, transistors, semiconductors, semiconductors switches, and other electronic devices. The electronic devices may generate heat during operation thereof. For example, semiconductor switches are sometimes used to switch circuit branches on and off within an electrical power distribution and/or supply system. The semiconductor switches generate heat during operation thereof. The heat generated by such electronic devices may cause the electronic device to malfunction and/or fail.

### BRIEF DESCRIPTION OF THE INVENTION

In one embodiment, a circuit board assembly includes first and second circuit boards that each include a substrate and a conductive circuit layer positioned on the substrate. The first and second circuit boards are arranged such that the conductive circuit layers face each other across a gap. Thermal conductor pillars extend lengths across the gap between the conductive circuit layers of the first and second circuit boards. The thermal conductor pillars include opposite first and second ends that are engaged in thermal contact with the conductive circuit layers of the first and second circuit boards, respectively. The thermal conductor pillars provide thermal pathways for heat to travel between the first and second circuit boards.

In another embodiment, a circuit board assembly includes first and second circuit boards that each include a substrate and a conductive circuit layer positioned on the substrate. The first and second circuit boards are arranged such that the conductive circuit layers face each other across a gap. An electronic device is mounted on the conductive circuit layer of the first circuit board in electrical connection therewith. Conductor pillars extend lengths across the gap between the conductive circuit layers of the first and second circuit boards. The conductor pillars are electrically conductive. The conductor pillars include opposite first and second ends that are engaged in electrical contact with the conductive circuit layers of the first and second circuit boards, respectively. The conductor pillars provide an electrical connection between the conductive circuit layers of the first and second circuit boards.

In another embodiment, a circuit board assembly includes first and second circuit boards each having a substrate and a conductive circuit layer positioned on the substrate. The first and second circuit boards are arranged such that the conductive circuit layers face each other across a gap. A semiconductor switch is mounted on the conductive circuit layer of the first circuit board in electrical connection therewith. The semiconductor switch is configured to switch circuit branches on and off. Conductor pillars extend lengths across the gap between the conductive circuit layers of the first and second circuit boards. The conductor pillars include opposite first and second ends that are engaged in at least one of thermal or electrical contact with the conductive circuit layers of the first and second circuit boards, respectively. The conductor pillars provide at least one of thermal pathways for heat to travel between the first and second circuit boards or an electrical connection between the conductive circuit layers of the first and second circuit boards.

### BRIEF DESCRIPTION OF THE DRAWINGS

FIG. 1 is a schematic diagram of an exemplary embodiment of a circuit board assembly.

FIG. 2 is a partially-broken away perspective view of a portion of an exemplary embodiment of a circuit board of the circuit board assembly shown in FIG. 1.

FIG. 3 is a perspective view of a portion of the circuit board assembly shown in FIG. 1.

FIG. 4 is another schematic diagram of the circuit board assembly shown in FIG. 1.

FIG. 5 is an elevational view of another embodiment of a circuit board assembly.

FIG. 6 is an elevational view of another embodiment of a circuit board assembly.

FIG. 7 is an elevational view of another embodiment of a circuit board assembly.

FIG. 8 is a schematic diagram of another embodiment of a circuit board assembly.

FIG. 9 is a cross-sectional view of another embodiment of a circuit board assembly.

FIG. 10 is a schematic diagram of another embodiment of a circuit board assembly.

### DETAILED DESCRIPTION OF THE INVENTION

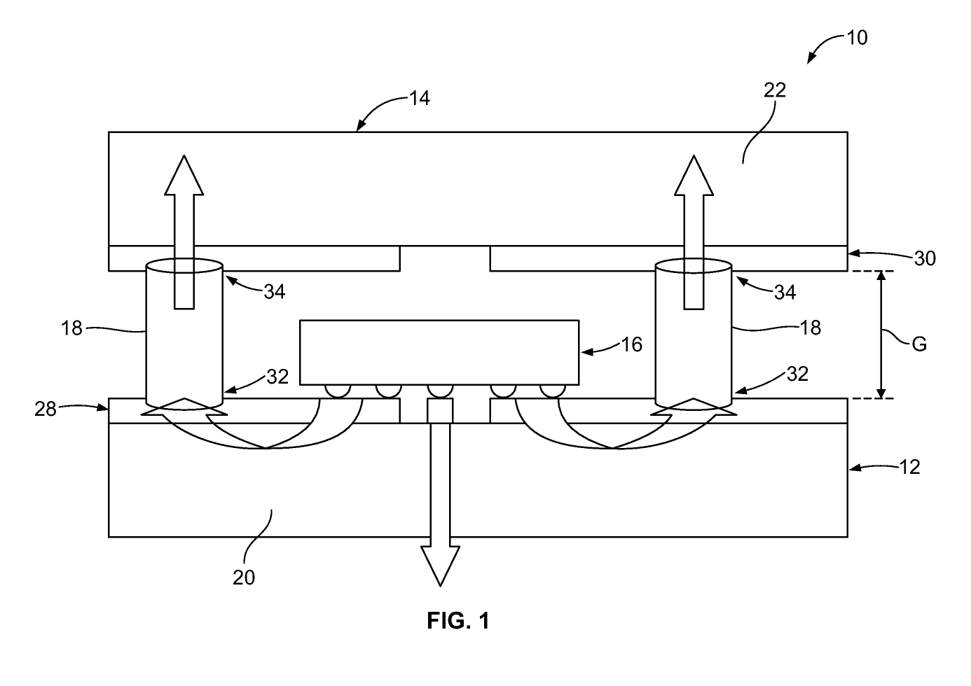

FIG. 1 is a perspective view of an exemplary embodiment of a circuit board assembly 10. The circuit board assembly 10 includes a circuit board 12, a circuit board 14, one or more electronic devices 16, and one or more thermal conductor pillars 18. The circuit boards 12 and 14 include respective substrates 20 and 22. The circuit boards 12 and 14 include respective conductive circuit layers 28 and 30 that are positioned on the substrates 20 and 22. The circuit boards 12 and 14 are arranged such that the conductive circuit layers 28 and 30 face each other across a gap G. In other words, the conductive circuit layers 28 and 30 face each other and are spaced apart by the gap G. Each of the circuit boards 12 and 14 may be referred to herein as a “first” and/or a “second” circuit board.

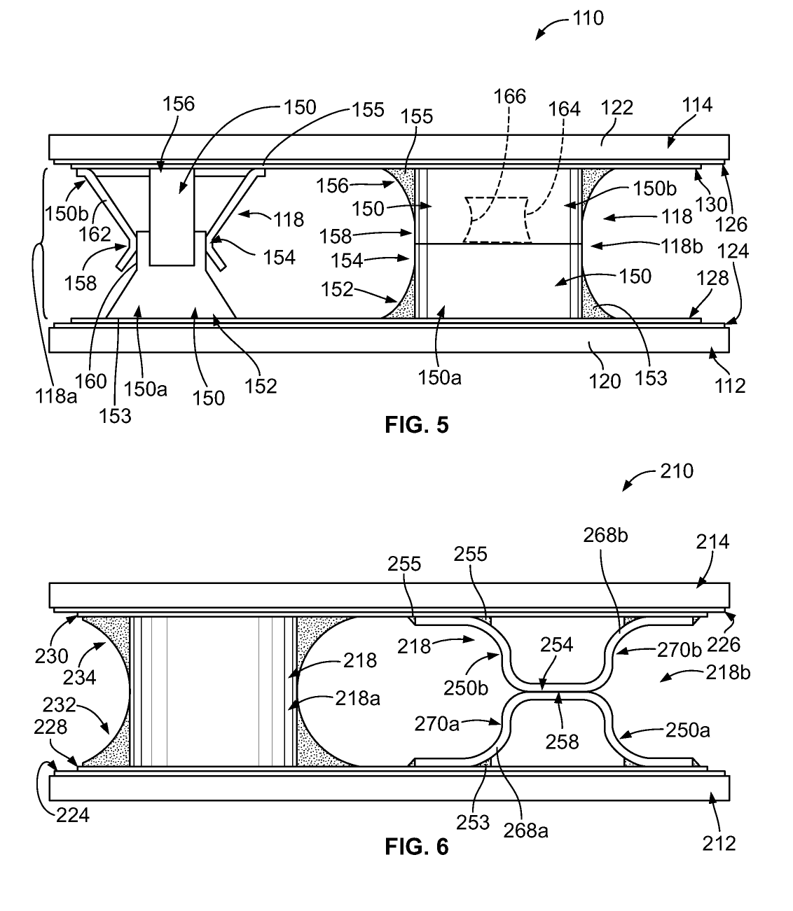

The substrates 20 and 22 are each a layer of the respective circuit board 12 and 14. As used herein, a layer positioned “on” another layer (or a surface thereof) is intended to mean that the layer is positioned directly on (i.e., in physical contact with) the other layer or that the layer is positioned directly on one or more intervening layers that extend between the layer and the other layer. For example, in the exemplary embodiment of the circuit board 14, the conductive circuit layer 30 is positioned directly on the substrate 22 such that the conductive circuit layer 30 physically contacts the substrate 22 of the circuit board 14. Moreover, and for example, in the exemplary embodiment of the circuit board 112 shown in FIG. 5, the conductive circuit layer 128 is positioned on the substrate 120 such that the conductive circuit layer 128 is positioned directly on a dielectric layer 124 that is positioned directly on the substrate 120.

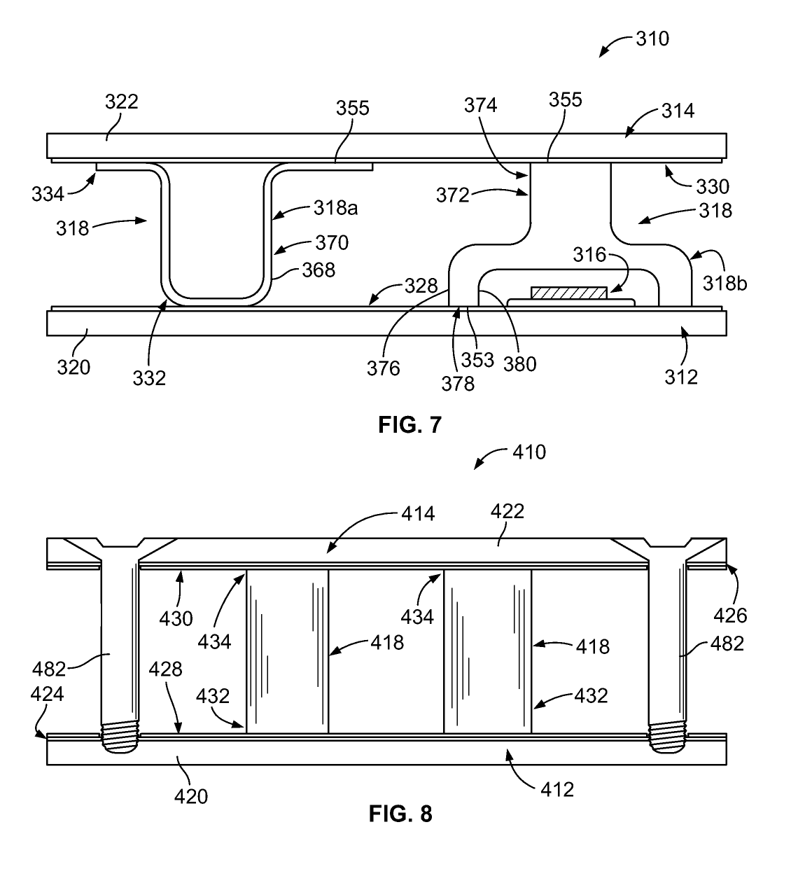

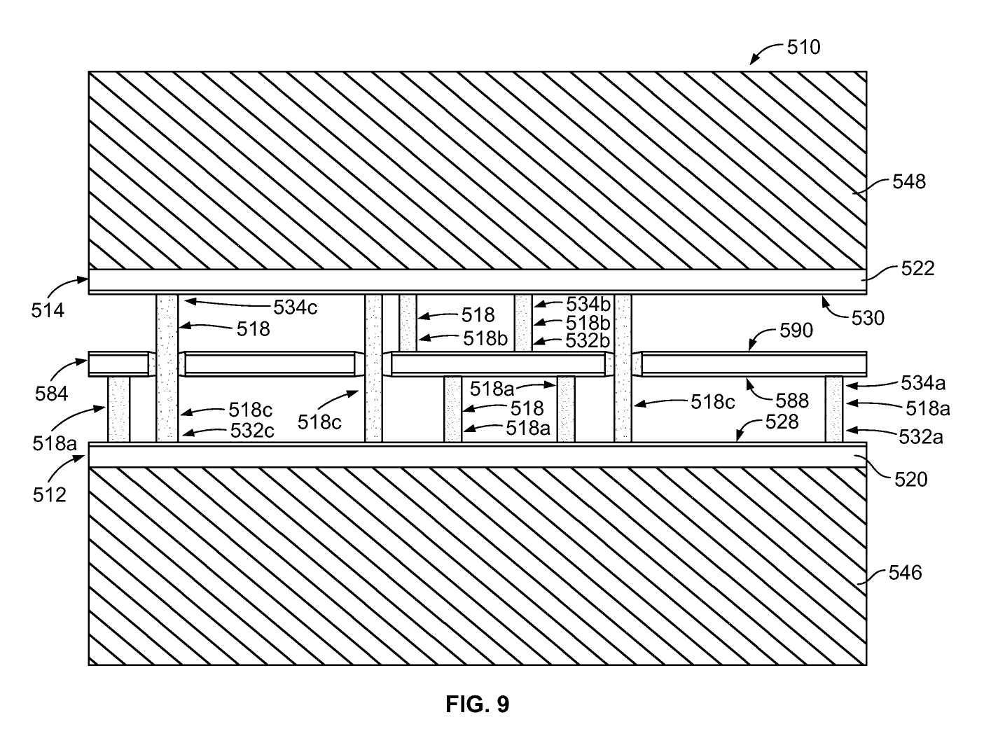

The circuit boards 12 and 14 may each be any type of circuit board having any type of substrate 20 and 22, respectively, such as, but not limited to, a metal substrate, a ceramic substrate, a direct bond copper substrate, a composite substrate, a substrate having a thermal conductivity k of at least approximately 100 W/(m·K), and/or the like. For example, the circuit board 12 and/or the circuit board 14 may be a conventional composite circuit board having a substrate that is fabricated from a composite material (e.g., epoxy glass, FR4, and/or the like). An example of a conventional composite circuit board 584 is shown in FIG. 9. Moreover, and for example, the circuit board 12 and/or the circuit board 14 may be a metal core circuit board having a metal substrate and a dielectric layer that extends between the metal substrate and the respective conductive circuit layer 28 and 30. Examples of metal core circuit boards are shown in FIGS. 5, 6, and 8. Another example of the circuit board 12 and/or the circuit board 14 is a ceramic circuit board that includes a ceramic substrate, wherein one or more dielectric layers may or may not extend between the ceramic substrate and the respective conductive circuit layer 28 and 30. An example of a ceramic substrate is shown in FIG. 7. In some embodiments, the circuit board assembly 10 includes a combination of two or more different types of circuit boards (e.g., two or more circuit boards having different types of substrates).

The circuit board 12 and/or the circuit board 14 may not include all of the layers shown and/or described herein with reference to the circuit board assembly 10. Moreover, the circuit board 12 and/or the circuit board 14 may include one or more additional layers that are not shown and/or described with reference to the circuit board assembly 10 (e.g., a dielectric layer that extends between the substrate 20 and the conductive circuit layer 28, a dielectric layer that extends between the substrate 22 and the conductive circuit layer 30, and/or the like). Although only two are shown, the circuit board assembly 10 may include any number of circuit boards, for example three or more circuit boards arranged in a stack similar to the stack of the two circuit boards 12 and 14 shown in FIG. 1. Each circuit board of the assembly 10 may have any number of electronic devices 16 mounted thereto. An electronic device 16 may be considered a layer of the circuit board 12 and/or 14 to which the electronic device is mounted.

In the exemplary embodiment of the circuit board assembly 10, the electronic device 16 is mounted on the conductive circuit layer 28 of the circuit board 12 in electrical connection with the conductive circuit layer 28. The thermal conductor pillars 18 extend lengths across the gap G between the conductive circuit layers 28 and 30. The thermal conductor pillars 18 include opposite ends 32 and 34 that may be engaged in thermal contact with the conductive circuit layers 28 and 30, respectively. As will be described in more detail below, the thermal conductor pillars 18 may provide thermal pathways for heat to travel between the circuit boards 12 and 14. The thermal conductor pillars 18 may be configured to dissipate heat from the electronic device 16 via the thermal pathways between the circuit boards 12 and 14. The ends 32 and 34 may each be referred to herein as a “first” and/or a “second” end.

The thermal conductor pillars 18 may be electrically conductive and the ends 32 and 34 of the thermal conductor pillars 18 may be engaged in electrical contact with the conductive circuit layers 28 and 30, respectively. The thermal conductor pillars 18 may thereby define electrical pathways between the conductive circuit layers 28 and 30 such that the thermal conductor pillars 18 provide an electrical connection between the conductive circuit layers 28 and 30. Moreover, in some embodiments, the thermal conductor pillars 18 provide a mechanical connection between the conductive circuit layers 28 and 30, and thus between the circuit boards 12 and 14.

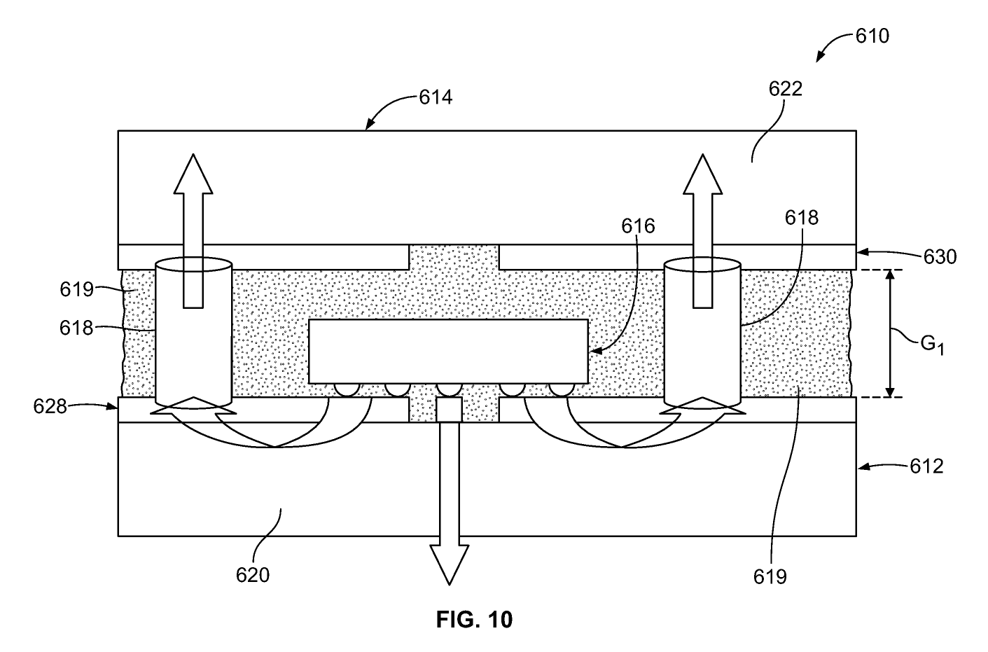

The thermal conductor pillars described and/or illustrated herein (e.g., the thermal conductor pillars 18, 118 (shown in FIG. 5), 218 (shown in FIG. 6), 318 (shown in FIG. 7), 418 (shown in FIG. 8), 518 (shown in FIG. 9), and 618 (shown in FIG. 10)) may provide any combination of thermal pathways, electrical pathways, and mechanical connections between conductive circuit layers. For example, in some embodiments, the thermal conductor pillars described and/or illustrated herein only provide thermal pathways, only provide electrical pathways, or only provide mechanical connections. Moreover, the thermal conductor pillars described and/or illustrated herein provide thermal pathways, electrical pathways, and mechanical connections in other embodiments. In other embodiments, the thermal conductor pillars described and/or illustrated herein provide both thermal pathways and electrical pathways, but not mechanical connections. In still other embodiments, the thermal conductor pillars described and/or illustrated herein provide both thermal pathways and mechanical connections, but not electrical pathways. In yet other embodiments, the thermal conductor pillars described and/or illustrated herein provide both electrical pathways and mechanical connections, but not thermal pathways. The thermal conductor pillars 18 may be referred to herein as “conductor pillars”.

The circuit board assembly 10 may be used with any type of electronic device 16, such as, but not limited to, active electronic devices, passive electronic devices, switches, diodes, resistors, relays, transistors, semiconductors, semiconductors switches, power diodes, power resistors, and/or the like. The term “electronic device” is intended to mean any electronic device that generates heat during operation thereof. As used herein, the phrase “generates heat during operation thereof” and the like is intended to mean any heating (e.g., temperature increase) of any component of, and any location on and/or within, the electronic device, for example heat that is generated by and/or within the electronic device as well as external heat that the electronic device is exposed to (e.g., an environmental and/or ambient temperature, heat from a neighboring object, and/or the like). The circuit board assembly 10 may be used for any application and within any larger host system. One example is using the circuit board assembly 10 within an electrical power distribution and/or supply system (not shown) wherein the electronic device 16 is a semiconductor switch used to switch circuit branches on and off. Other exemplary applications of the circuit board assembly 10 include, but are not limited to, within a light emitting diode (LED) assembly (not shown), within an antenna (not shown), and/or the like.

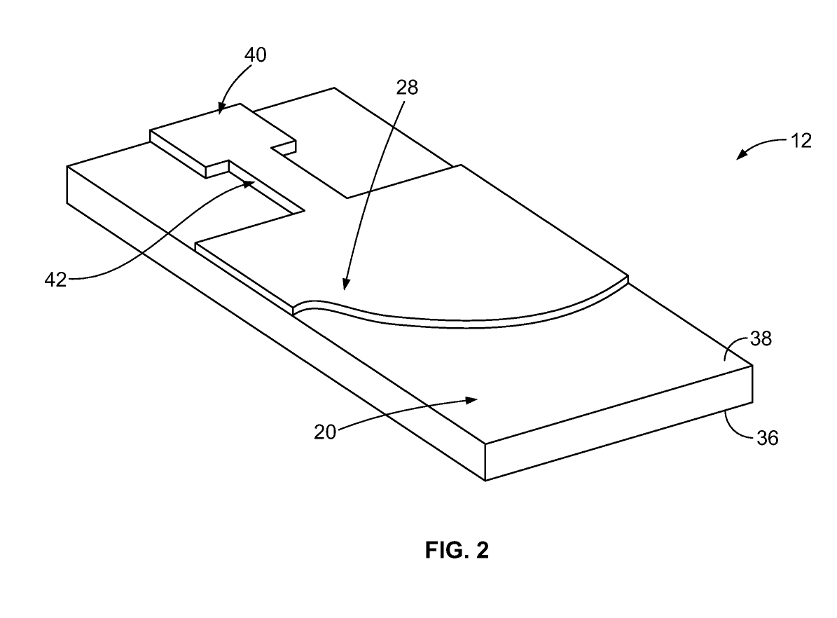

FIG. 2 is a partially broken-away perspective view of a portion of an exemplary embodiment of the circuit board 12. The circuit board 12 includes the substrate 20 and the conductive circuit layer 28 positioned on the substrate 20. Portions of the conductive circuit layer 28 have been removed in FIG. 2 to illustrate the exemplary structure of the circuit board 12. The circuit board 12 may have other layers in alternative embodiments, which may be interspersed between the layers identified above. The circuit board 12 may be manufactured with fewer or more layers in alternative embodiments.

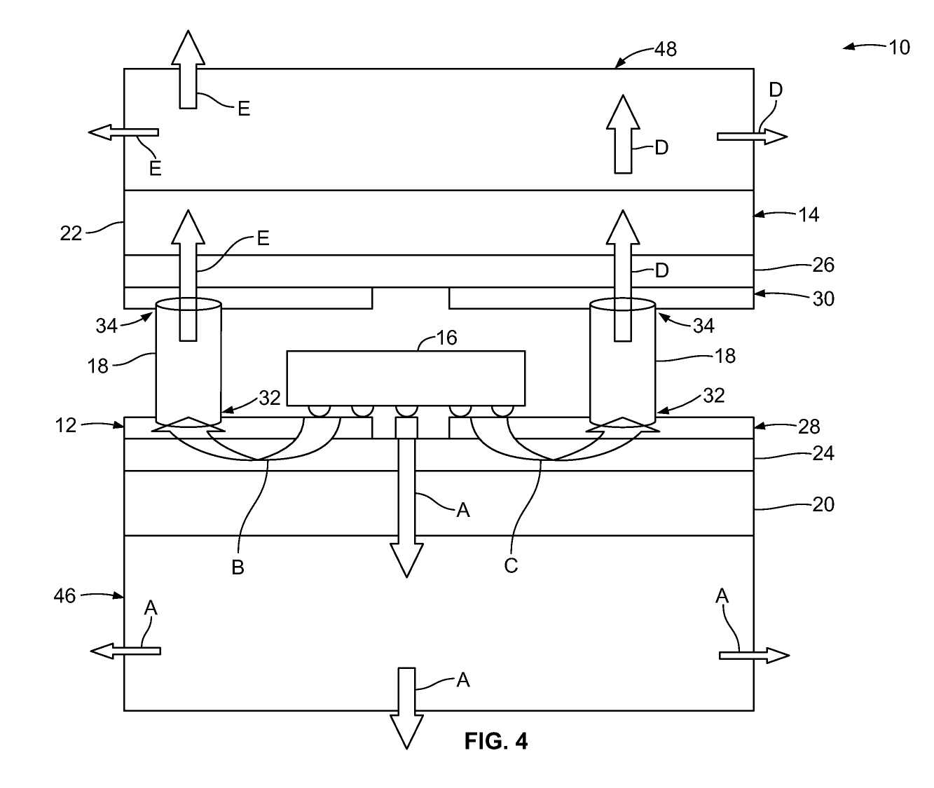

The substrate 20 of the circuit board 12 extends between a bottom surface 36 and an opposite top surface 38. The substrate 20 has a thickness measured between the surfaces 36 and 38. The bottom surface 36 is optionally configured to be mounted to a heat sink (not shown in FIG. 2, e.g., the heat sink 46 shown in FIG. 4). For example, the substrate 20 may be configured to provide heat transfer to the heat sink to cool the components mounted to the circuit board 12, such as, but not limited to, the electronic devices 16 (FIGS. 1, 3, and 4). Optionally, a thermal interface material (not shown) may be applied to the bottom surface 36 for interfacing with the heat sink. The substrate 20 is optionally fabricated such that the substrate 20 has a sufficiently high thermal conductivity (e.g., a thermal conductivity k of at least approximately 100 W/(m·K)) that enables the substrate 20 to transfer heat to the heat sink.

In the exemplary embodiment of the circuit board 12, the conductive circuit layer 28 is positioned directly on the top surface 38 of the substrate 20. The conductive circuit layer 28 includes various electrical contacts 40, electrical traces 42, wire bonds (not shown), and/or electrical vias (not shown) that define electrical connections and/or electrical pathways of the circuit board 12. The electrical contacts 40, the electrical traces 42, the wire bonds, and the electrical vias may have any pattern. The conductive circuit layer 28 may include any materials such as, but not limited to, copper, silver, lead, tin, and/or the like. Optionally, the conductive circuit layer 28 includes a conductive seed layer (not shown). One or more portions, or an entirety, of the conductive circuit layer 28 optionally includes an over-plating of other elements (such as, but not limited to, tin and/or the like), for example to provide environmental protection and/or a solderable surface. In addition to the conductive circuit layer 28 positioned on the top surface 38 of the substrate 20, the circuit board 12 may include another conductive circuit layer (not shown) that is positioned on the bottom surface 36 of the substrate 20 and/or may include one or more other conductive circuit layers (not shown) that is an internal layer of the circuit board 12. In other words, the circuit board 12 optionally includes another conductive circuit layer that is positioned on an opposite side of the substrate 20 as compared to the conductive circuit layer 28.

In the exemplary embodiment of the circuit board assembly 10, the circuit board 14 (FIGS. 1 and 4) is substantially similar to the circuit board 12. Accordingly, the circuit board 14 will not be described in more detail herein. But, as described above, in some alternative embodiments the circuit board 14 is a different type of circuit board from the circuit board 12. For example, the circuit board 14 may include a different number of layers than the circuit board 12, the circuit board 14 may include one or more different types of layers than the circuit board 12, the circuit board 12 may have a different arrangement of layers than the circuit board 12, the substrate 22 of the circuit board 14 may be a different type (e.g., fabricated from one or more different materials) of substrate than the substrate 20 of the circuit board 12, and/or the like.

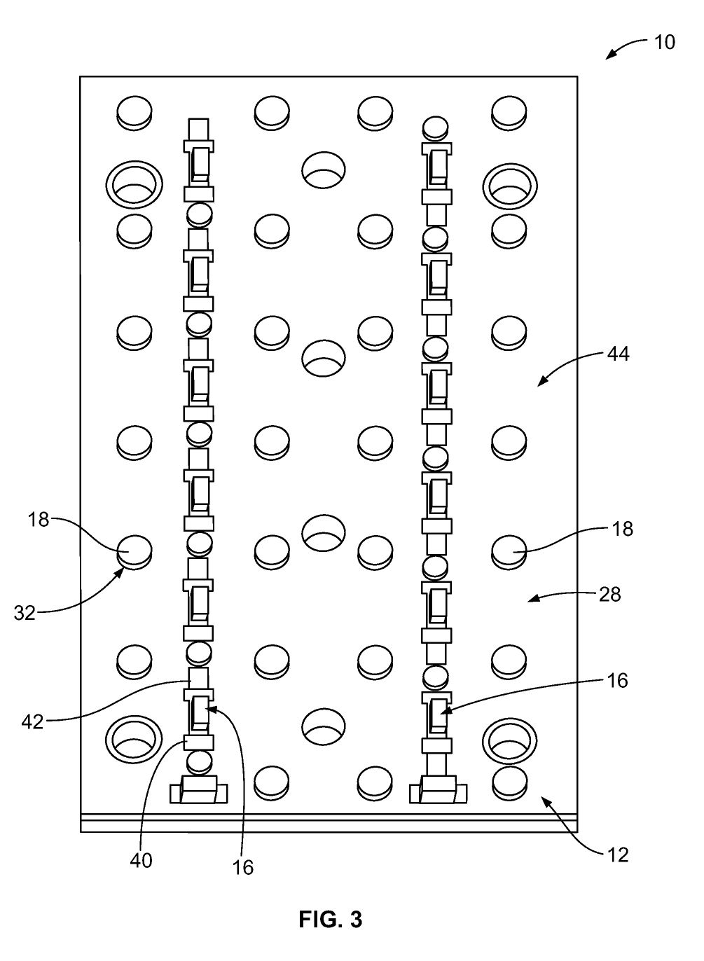

FIG. 3 is a perspective view of a portion of the circuit board assembly 10 illustrating the electronic devices 16 and the thermal conductor pillars 18 mounted to the circuit board 12. The circuit board 12 may have a variety of shapes of sizes depending on the particular application. In the exemplary embodiment of the circuit board 12, the circuit board 12 is elongated and rectangular in shape. Other exemplary shapes of the circuit board 12 include, but are not limited to, a generally square shape, a generally circular shape, a generally oval shape, a generally triangular shape, and/or the like.

The electronic devices 16 are mounted to a side 44 of the circuit board 12. Specifically, each electronic device 16 is mounted to one or more electrical contacts 40, electrical vias, wire bonds, and/or electrical traces 42 of the conductive circuit layer 28 in electrical connection therewith. The electronic devices 16 may be mounted to the corresponding electrical contact 40, electrical via, wire bond, and/or electrical trace 42 using any suitable method, means, structure, connection type, and/or the like, such as, but not limited to, using engagement therebetween, using solder, using an electrically conducive epoxy, being die-attached and wire bonded, and/or the like. Each electronic device 16 may be any type of electronic device, such as, but not limited to, an active electronic device, a passive electronic device, a switch, a relay, a diode, a resistor, a transistor, a semiconductor, a semiconductor switch, a power diode, a power resistor, and/or the like. Although twelve are shown in FIG. 3, the circuit board 12 may include any number of the electronic devices 16 mounted thereto. Moreover, the electronic devices 16 may be arranged in any other pattern than is shown herein. The circuit board 12 may include other electronic components mounted to the side 44 of the circuit board 12. For example, the circuit board 12 may include other electronic components, such as, but not limited to, capacitors, resistors, sensors, and/or the like on the side 44. In addition or alternative to the electronic devices 16 mounted to the circuit board 12, the circuit board 14 (FIGS. 1 and 4) may include one or more electronic devices 16 mounted thereto.

The thermal conductor pillars 18 are shown mounted to the side 44 of the circuit board 12. The end 32 of each thermal conductor pillar 18 may be mounted to the side 44 in thermal contact with the conductive circuit layer 28. For example, the ends 32 may be mounted in thermal contact with one or more electrical contacts 40, one or more electrical vias, one or more wire bonds, one or more electrical traces 42, and/or one or more other segments of the conductive circuit layer 28. The ends 32 of the thermal conductor pillars 18 may be mounted to the conductive circuit layer 28 in thermal contact therewith using engagement therebetween, solder, an epoxy, and/or the like. The term “thermal contact” is intended to mean an arrangement between two items wherein heat is thermally conducted between the two items. Optionally, one or more of the thermal conductor pillars 18 is electrically conductive and is electrically connected to the conductive circuit layer 28, for example to one or more electrical contacts 40, one or more electrical vias, one or more wire bonds, and/or one or more electrical traces 42 of the conductive circuit layer 28. The end 32 of a thermal conductor pillar 18 may be electrically connected to the conductive circuit layer 28 using engagement therebetween, solder, an electrically conductive epoxy, and/or the like.

Optionally, the ends 32 of the thermal conductor pillars 18 are mechanically connected to the conductive circuit layer 28, for example to the one or more electrical contacts 40, the one or more electrical vias, the one or more wire bonds, the one or more electrical traces 42, and/or the one or more other segments of the conductive circuit layer 28. The ends 32 of the thermal conductor pillars 18 may be mechanically connected to the conductive circuit layer 28 using any suitable method, means, structure, fastener, and/or the like, such as, but not limited to, solder, an epoxy, an adhesive, a press-fit, a collar, a clamp, a threaded fastener, a clip, and/or the like.

The thermal conductor pillars 18 may be configured to conduct heat. Specifically, the thermal conductor pillars 18 may have a relatively low thermal resistance and a relatively high thermal conductivity. Examples of a relatively high thermal conductivity k of the thermal conductor pillars 18 include, but are not limited to, greater than approximately 100 W/(m·K), greater than approximately 200 W/(m·K), greater than approximately 300 W/(m·K), and/or the like. The number, size (e.g., length, diameter, width, thickness, and/or the like), shape, and/or the material of the thermal conductor pillars 18 may be selected to affect the thermal conductivity and/or thermal resistivity properties of the thermal conductor pillars 18. Different types of materials may be used in various embodiments, such as, but not limited to, a metal, ceramic, graphite, copper, aluminum, and/or the like. The thermal conductor pillars may be fabricated from any materials, may have any size, and may have any shape, which may be selected to provide the thermal conductor pillars 18 with a predetermined thermal conductivity and/or thermal resistance. In the exemplary embodiments of the thermal conductor pillars 18, the thermal conductor pillars 18 have cylindrical shapes. Examples of cylindrical shapes of the thermal conductor pillars 18 include, but are not limited to, circular cylinders, elliptic cylinders, parabolic cylinders, hyperbolic cylinders, conical cylinders, frusto-conical cylinders, and/or the like. But, the thermal conductor pillars 18 may include any shape (e.g., in addition or alternative a cylindrical shape), such as, but not limited to, a non-cylindrical shape, a sinewy shape, a bent shape, a plus shape, a cross shape, a wavy corrugation shape, a honeycomb shape, an H-shape, an elongated rectangular shape, a rectangular cross-sectional shape, a square cross-sectional shape, a triangular cross-sectional shape, an oval cross-sectional shape, and/or the like. Any number of thermal conductor pillars 18 may be provided. Although shown as being formed from a single continuous structure, each thermal conductor pillar 18 may alternatively be formed from two or more discrete structures that engage (i.e., physically contact) and/or interlock to define the thermal conductor pillar 18.

The illustrated pattern of the thermal conductor pillars 18 along the side 44 of the circuit board 12 is exemplary only. The thermal conductor pillars 18 are not limited to the pattern shown herein, but rather may have any other pattern. The pattern of the thermal conductor pillars 18 along the side 44 may be selected to provide a predetermined amount of spacing between adjacent thermal conductor pillars 18. For example, the spacing between adjacent thermal conductor pillars 18 may be selected to increase the efficiency of the thermal conductor pillars 18 in conducting heat along the lengths thereof and/or to increase the amount of heat dissipated by the thermal conductor pillars 18 into the spaces between adjacent thermal conductor pillars 18.

FIG. 4 is another schematic diagram of the circuit board assembly 10. In the exemplary embodiment of the circuit board 14, the circuit board 14 does not include any of the electronic devices 16 mounted thereto. Alternatively, one or more electronic devices 16 are mounted to the circuit board 14 (whether or not any electronic devices 16 are mounted to the circuit board 12).

The ends 34 of the thermal conductor pillars 18 are illustrated in FIG. 4 as mounted to the conductive circuit layer 30 of the circuit board 14. The ends 34 of the thermal conductor pillars 18 are mounted to the conductive circuit layer 30 of the circuit board 14 in a substantially similar manner to how the ends 32 are mounted to the conductive circuit layer 28 of the circuit board 12. The end 34 of one or more of the thermal conductor pillars 18 may be in thermal contact with, may be electrically connected to, and/or may be mechanically connected to the conductive circuit layer 30 in an identical or substantially similar manner to the thermal contact, electrical connection, and/or mechanical connection between the ends 32 and the conductive circuit layer 28. Although shown as being mounted to the circuit board 12 before being mounted to the circuit board 14, the thermal conductor pillars 18 may be mounted to the circuit board 14 before being mounted to the circuit board 12 or may be mounted to the circuit boards 12 and 14 simultaneously.

The circuit boards 12 and 14 are arranged such that the conductive circuit layers 28 and 30 face each other across the gap G. The thermal conductor pillars 18 extend the lengths across the gap G between the conductive circuit layers 28 and 30. The lengths of the thermal conductor pillars 18 may be selected to provide the gap G with a predetermined dimension, for example to provide a predetermined amount of space for accommodating one or more electronic devices 16. Optionally, the circuit board 12 and/or the circuit board 14 is mounted, whether directly or indirectly, to a respective heat sink 46 and 48. Specifically, in the exemplary embodiment of the circuit board assembly 10, the substrates 20 and 22 of the circuit boards 12 and 14, respectively, are mounted directly to the respective heat sinks 46 and 48. The heat sinks 46 and 48 may each have any structure and/or be any type of heat sink. For example, the heat sinks 46 and/or 48 may include one or more fins (not shown) for increasing the surface area of the heat sink 46 and/or 48. Moreover, and for example, the heat sinks 46 and/or 48 may be a component of a larger system within which the circuit board assembly 10 is used, such as, but not limited to, a body panel (e.g., of a vehicle), a wall, a chassis, a frame, an airframe, and/or another structure of a building, a vehicle (e.g., an aircraft), and/or the like. As described above, in some embodiments, the substrates 20 and/or 22 are mounted indirectly to the heat sinks 46 and/or 48, respectively. For example, the heat sink 46 and/or 48 may be a remote heat sink that is thermally connected to the respective substrate 20 and 22 via one or more saddles (not shown), one or more heat pipes (not shown), and/or the like. Moreover, in addition or alternatively to the heat sink 46 and/or the heat sink 48, the substrates 20 and/or 22 may be mounted, whether directly or indirectly, to another type of heat reservoir, such as, but not limited to, a cooling plate, a liquid tank and/or other container, and/or the like.

The thermal conductor pillars 18 optionally provide thermal pathways for heat to travel between the circuit boards 12 and 14. The thermal conductor pillars 18 may be configured to dissipate heat from the electronic devices 16 via the thermal pathways between the circuit boards 12 and 14. Specifically, in the exemplary embodiment of the circuit board assembly 10, heat generated from the electronic devices 16 is conducted through the circuit board 12. Some of the heat travels through the conductive circuit layer 28, through the substrate 20, and to the heat sink 46 for dissipation to the environment, as indicated by the arrow A in FIG. 4. Some of the heat generated from the electronic device 16 travels through the conductive circuit layer 28 to the ends 32 of the thermal conductor pillars 18, as indicated by the arrows B and C in FIG. 4. The thermal conductor pillars 18 conduct the heat along the lengths of the thermal conductor pillars 18 through the ends 34 to the conductive circuit layer 30 of the circuit board 14. The heat travels through the conductive circuit layer 30, through the substrate 22, and to the heat sink 48 for dissipation to the environment, as indicated by the arrows D and E in FIG. 4.

As described above, one or more of the thermal conductor pillars 18 is optionally electrically conductive. In the exemplary embodiment of the circuit board assembly 10, the thermal conductor pillars 18 are electrically conductive and form electrical connections between the circuit boards 12 and 14. Specifically, the ends 32 and 34 of the thermal conductor pillars 18 are electrically connected to the conductive circuit layers 28 and 30, respectively, such that the thermal conductor pillars 18 define electrical pathways between the conductive circuit layers 28 and 30. Any number of the thermal conductor pillars 18 may be electrically conductive and provide an electrical connection between the circuit boards 12 and 14. It should be appreciated that during operation of the electronic devices 16, the thermal conductor pillars 18 may simultaneously distribute both heat and electrical current along and/or within the circuit board assembly 10.

As is also described above, the ends 32 and/or 34 of the thermal conductor pillars 18 are optionally mechanically connected to the respective conductive circuit layers 28 and 30. When both of the ends 32 and 34 are mechanically connected to the respective conductive circuit layers 28 and 30, the thermal conductor pillars 18 provide a mechanical connection between the conductive circuit layers 28 and 30, and thus between the circuit boards 12 and 14. The mechanical connection provided by the thermal conductor pillars 18 may facilitate holding the circuit boards 12 and 14 together as shown in FIGS. 1 and 4. In other words, the thermal conductor pillars 18 may facilitate preventing the circuit boards 12 and 14 from separating from each other. The mechanical connection provided by the thermal conductor pillars 18 may thus facilitate maintaining any electrical and/or thermal connections between the circuit boards 12 and 14. In embodiments wherein the thermal conductor pillars 18 mechanically connect the conductive circuit layers 28 and 30, the thermal conductor pillars 18 may simultaneously maintain the structural integrity of the circuit board assembly 10 and/or distribute heat and/or electrical current along and/or within the circuit board assembly 10 during operation of the electronic devices 16.

The circuit board assembly 10, and more particularly the thermal conductor pillars 18 and the arrangement of the circuit boards 12 and 14, facilitates dissipating heat from the one or more electrical devices 16. The circuit board assembly 10 may thereby facilitate protecting the electrical devices 16 from overheating and thereby malfunctioning or failing. The circuit board assembly 10 may be more effective at dissipating heat from one or more electrical devices 16 than at least some known circuit boards.

In embodiments wherein the thermal conductor pillars 18 are electrically conductive, the thermal conductor pillars 18 may reduce the ohmic resistance of the conductive circuit layer 28 and/or 30 by effectively increasing the cross-sectional area of the layer 28 and/or 30, thereby decreasing the resistance of the layer 28 and/or 30. Specifically, the thermal conductor pillars 18 may enable corresponding electrical traces 42 of the conductive circuit layers 28 and 30 to be in parallel. Such a parallel arrangement enables less current to flow in each trace 42 and provides a greater surface area of the trace 42, which in turn provides an increased thermal coupling to the substrates 20 and/or 22. For example, heat removal and/or dissipation may be improved by effectively increasing the cross-sectional area of the circuit board assembly 10. Moreover, and for example, the electrical resistance of the conductive circuit layer 28 and/or 30 may be reduced by increasing the effective cross-sectional area of the layer 28 and/or 30. Moreover, the thermal conductor pillars 18 can provide electrical paths for gating signals, data signals, and/or the like that may otherwise impede or worsen the paths of electrical traces 42. Further, thermal conductor pillars 18 that are electrically conductive may reduce the path length of traces 42 of the conductive circuit layer 28 and/or 30 by providing shortcut electrical pathways. The use of electrical traces 42 within both of the conductive circuit layers 28 and 30 may enable simpler electrical connections for control signals, more efficient power traces, and/or the like.

FIG. 5 is an elevational view of another embodiment of a circuit board assembly 110 illustrating another embodiment of thermal conductor pillars 118. The circuit board assembly 110 includes circuit board 112 and 114, one or more electronic devices (not shown), and the thermal conductor pillars 118. In the exemplary embodiment of the circuit board assembly 110, the circuit boards 112 and 114 are each metal core circuit boards that include respective metal substrates 120 and 122, respective dielectric layers 124 and 126 positioned on the metal substrates 120 and 122, and respective conductive circuit layers 128 and 130 positioned on the metal substrates 120 and 122. In the exemplary embodiment of the circuit board assembly 110, the dielectric layers 124 and 126 are positioned directly on the metal substrates 120 and 122, respectively, and the conductive circuit layers 128 and 130 are positioned directly on the dielectric layers 124 and 126, respectively. The circuit board 112 and/or the circuit board 114 may include one or more of the electronic devices (e.g., the electronic devices 16 shown in FIGS. 1, 3, and 4) mounted thereto. The circuit boards 112 and 114 are arranged such that the conductive circuit layers 128 and 130 face each other across a gap. Each of the circuit boards 112 and 114 may be referred to herein as a “first” and/or a “second” circuit board. The thermal conductor pillars 118 may be referred to herein as “conductor pillars”.

The metal substrates 120 and 122 of the metal core circuit boards 112 and 114, respectively, may provide better thermal transfer than other types of circuit boards, for example circuit boards manufactured from glass epoxy or FR4 materials. The metal substrates 120 and 122 may provide a mechanically robust substrate that is not as fragile as other types of circuit boards. The metal core circuit boards 112 and 114 may provide relatively low operating temperatures for the electronic devices and may have increased thermal efficiency for dissipating heat from the electronic devices. The metal core circuit boards 112 and 114 may have relatively high durability and may have a reduced size by limiting the need for an additional heat transfer layer. The metal substrates 120 and 122 may be fabricated from a material having a relatively high thermal conductivity (e.g., at least approximately 100 W/(m·K)), such as, but not limited to, an aluminum material, a copper material, and/or the like. The metal substrates 120 and 122 may efficiently transfer heat from the electronic devices mounted to the metal core circuit boards 112 and/or 114.

The dielectric layer 124 of the metal core circuit board 112 is positioned between the metal substrate 120 and the conductive circuit layer 128. The dielectric layer 124 electrically isolates the metal substrate 120 from the conductive circuit layer 128. The dielectric layer 126 of the metal core circuit board 114 is positioned between the metal substrate 122 and the conductive circuit layer 130. The dielectric layer 126 electrically isolates the metal substrate 122 from the conductive circuit layer 130. The dielectric layers 124 and/or 126 may have a sufficiently low thermal resistance and a sufficiently high thermal conductivity so that effective thermal transfer can occur to the metal substrates 120 and/or 122. The dielectric layers 124 and/or 126 may each have any thermal conductivity k. The thickness of the dielectric layers 124 and/or 126, as well as the type of material used for the dielectric layers 124 and/or 126, may affect the thermal conductivity, the thermal resistivity, and/or the dielectric properties of the dielectric layers 124 and/or 126. In some embodiments, the dielectric layers 124 and/or 126 are sufficiently thin to allow effective thermal transfer through the dielectric layers 124 and/or 126 to the metal substrates 120 and/or 122, respectively. Moreover, in some embodiments, the thickness of the dielectric layers 124 and/or 126 is balanced with one or more electrical properties (e.g., breakdown voltage and/or the like) of the dielectric layers 124 and/or 126 to provide the dielectric layers 124 and/or 126 with a predetermined balance of thermal and electrical properties.

Different types of dielectric materials may be used in various embodiments, such as, but not limited to, polymer particles, epoxies, and/or the like. Optionally, the dielectric layer 124 and/or 126 includes fillers and/or other particles mixed in with the polymers to change properties of the dielectric layers 124 and/or 126, such as, but not limited to, the thermal conductivity, the thermal resistance, and/or the thermal efficiency of the dielectric layers 124 and/or 126. For example, particles such as alumina and/or boron nitride particles may be added to the polymer particles to make the dielectric layers 124 and/or 126 more thermally conductive. Other types of fillers and/or other particles may be added to the mixture to change other characteristics of the dielectric layers 124 and/or 126. The materials used to fabricate the dielectric layers 124 and/or 126 may be powders, films, epoxies, other forms, and/or the like.

In the exemplary embodiment of the circuit board assembly 110, each thermal conductor pillar 118 is formed from two or more mating elements 150 that separably mate together to form the thermal conductor pillar 118. Specifically, each thermal conductor pillar 118 includes mating elements 150a and 150b. In the exemplary embodiment of the circuit board assembly 110, the mating element 150a is mounted to the conductive circuit layer 128 of the circuit board 112 such that a mounting end 152 of the mating element 150a is mechanically connected to the conductive circuit layer 128 using a component 153 that is discrete from, and engaged with (i.e., physically contacts), both the mounting end 152 and the conductive circuit layer 128. In other words, the mounting end 152 and the conductive circuit layer 128 are more than merely engaged with each other. In the exemplary embodiment of the circuit board assembly 110, the mounting end 152 is mechanically connected to the conductive circuit layer 128 in thermal and electrical contact therewith. The discrete component 153 that mechanically connects the mounting end 152 to the conductive circuit layer 128 is solder in the exemplary embodiment of the circuit board assembly 110. But, the mounting end 152 may be mechanically connected to the conductive circuit layer 128 using any other discrete component, such as, but not limited to, an epoxy, an adhesive, a press-fit, a collar, a clamp, a threaded fastener, a clip, and/or the like. The mounting end 152 of the mating element 150a is in thermal and electrical contact with the conductive circuit layer 128 in the exemplary embodiment of the circuit board assembly 110. The mating element 150a includes a mating end 154 that is configured to separably mate with the mating element 150b of the thermal conductor pillar 118. The mounting end 152 may be referred to herein as a “first” and/or a “second” end.

In the exemplary embodiment of the circuit board assembly 110, the mating element 150b is mounted to the conductive circuit layer 130 of the circuit board 114 such that a mounting end 156 of the mating element 150b is mechanically connected to the conductive circuit layer 130 using a component 155 that is discrete from, and engaged with (i.e., physically contacts), both the mounting end 156 and the conductive circuit layer 130. In other words, the mounting end 156 and the conductive circuit layer 130 are more than merely engaged with each other. In the exemplary embodiment of the circuit board assembly 110, the mounting end 156 is mechanically connected to the conductive circuit layer 130 in thermal and electrical contact therewith. The discrete component 155 that mechanically connects the mounting end 156 to the conductive circuit layer 130 is solder in the exemplary embodiment of the circuit board assembly 110. But, the mounting end 156 may be mechanically connected to the conductive circuit layer 130 using any other discrete component, such as, but not limited to, an epoxy, an adhesive, a press-fit, a collar, a clamp, a threaded fastener, a clip, and/or the like. The mating element 150b includes a mating end 158 that is configured to separably mate with the mating element 150a. The mounting end 156 may be referred to herein as a “first” and/or a “second” end.

As shown in FIG. 5, the mating ends 154 and 158 of the mating elements 150a and 150b mate together to complete the thermal conductor pillar 118. When mated together as shown in FIG. 5, the mating elements 150a and 150b are in thermal contact with each other such that the thermal conductor pillar 118a forms a thermal pathway for heat to travel between the circuit boards 112 and 114. The mating elements 150a and 150b also establish an electrical connection therebetween when mated together, such that the thermal conductor pillar 118a provides an electrical pathway between the circuit boards 112 and 114.

The mating elements 150 that mate together to complete the thermal conductor pillar 118 enable the circuit boards 112 and 114 to be separated, or unmated, from each other, for example for service, repair, maintenance, replacement, swapability, and/or the like. Although shown as including two mating elements 150, each thermal conductor pillar 118 may include any number of mating elements 150. In some embodiments, additional mating elements 150 may be added to a thermal conductor pillar 118 to increase the size of the gap between the circuit boards 112 and 114, for example to accommodate the addition of a larger electronic device.

The mating ends 154 and 158 of mating elements 150a and 150b may mate together using any geometry, structure, means, connection type, and/or the like, such as, but not limited to, using a snap-fit, using an interference-fit, using a spring, using a pin, using a receptacle, using a plug, using a button, using an opening, using a slot, and/or the like. For example, the mating end 154 of the mating element 150a of a thermal conductor pillar 118a includes a plug 160 that is configured to be grasped by spring arms 162 of the mating end 158 of the mating element 150b of the thermal conductor pillar 118a. Moreover, and for example, the mating end 154 of the mating element 150a of a thermal conductor pillar 118b includes a button 164 that is configured to be received with a snap-fit within an opening 166 of the mating end 158 of the mating element 150b of the thermal conductor pillar 118b.

FIG. 6 is an elevational view of another embodiment of a circuit board assembly 210 illustrating another embodiment of thermal conductor pillars 218. The circuit board assembly 210 includes circuit boards 212 and 214, one or more electronic devices (not shown) mounted to the circuit boards 212 and/or 214, and the thermal conductor pillars 218. In the exemplary embodiment of the circuit board assembly 210, the circuit boards 212 and 214 are each metal core circuit boards that include respective metal substrates 220 and 222, respective dielectric layers 224 and 226 positioned on the metal substrates 220 and 222, and respective conductive circuit layers 228 and 230 positioned on the metal substrates 220 and 222. In the exemplary embodiment of the circuit board assembly 210, the dielectric layers 224 and 226 are positioned directly on the metal substrates 220 and 222, respectively, and the conductive circuit layers 228 and 230 are positioned directly on the dielectric layers 224 and 226, respectively. Each of the circuit boards 212 and 214 may be referred to herein as a “first” and/or a “second” circuit board. The thermal conductor pillars 218 may be referred to herein as “conductor pillars”.

Two thermal conductor pillars 218 are shown in FIG. 6. One of the thermal conductor pillars 218a is a solid circular cylinder having opposite ends 232 and 234 that are mechanically connected to the conductive circuit layers 228 and 230, respectively. In the exemplary embodiment of the circuit board assembly 210, the ends 232 and 234 are soldered to the conductive circuit layers 228 and 230, respectively. But, the ends 232 and 234 may be mechanically connected to the respective conductive circuit layers 228 and 230 using any suitable method, means, structure, fastener, and/or the like, such as, but not limited to, an epoxy, an adhesive, a press-fit, a collar, a clamp, a threaded fastener, a clip, and/or the like. The ends 232 and 234 may each be referred to herein as a “first” and/or a “second” end.

The other thermal conductor pillar 218b includes two mating elements 250a and 250b that separably mate together via engagement (i.e., physical contact) therebetween to complete the thermal conductor pillar 218b. The mating elements 250a and 250b are formed from respective segments 268a and 268b that are discrete components from the conductive circuit layers 228 and 230. In the exemplary embodiment of the circuit board assembly 210, the segment 268a is mounted to the conductive circuit layer 228 such that the mating element 250a is mechanically connected to the conductive circuit layer 228 using a component 253 that is discrete from, and engaged with (i.e., physically contacts), both the segment 268a and the conductive circuit layer 228. In other words, the segment 268a and the conductive circuit layer 228 are more than merely engaged with each other. In the exemplary embodiment of the circuit board assembly 210, the segment 268a is mechanically connected to the conductive circuit layer 228 in thermal and electrical contact therewith. The discrete component 253 that mechanically connects the segment 268a to the conductive circuit layer 228 is solder in the exemplary embodiment of the circuit board assembly 210. But, the segment 268a may be mechanically connected to the conductive circuit layer 228 using any other discrete component, such as, but not limited to, an epoxy, an adhesive, a press-fit, a collar, a clamp, a threaded fastener, a clip, and/or the like.

In the exemplary embodiment of the circuit board assembly 210, the segment 268b is mounted to the conductive circuit layer 230 such that the mating element 250b is mechanically connected to the conductive circuit layer 230 using a component 255 that is discrete from, and engaged with (i.e., physically contacts), both the segment 268b and the conductive circuit layer 230. In other words, the segment 268b and the conductive circuit layer 230 are more than merely engaged with each other. In the exemplary embodiment of the circuit board assembly 210, the segment 268b is mechanically connected to the conductive circuit layer 230 in thermal and electrical contact therewith. The discrete component 255 that mechanically connects the segment 268b to the conductive circuit layer 230 is solder in the exemplary embodiment of the circuit board assembly 210. But, the segment 268b may be mechanically connected to the conductive circuit layer 230 using any other discrete component, such as, but not limited to, an epoxy, an adhesive, a press-fit, a collar, a clamp, a threaded fastener, a clip, and/or the like.

The segments 268a and 268b are bent to define respective sub-pillars 270a and 270b of the mating elements 250a and 250b. The sub-pillars 270a and 270b include mating ends 254 and 248 that separably mate together to complete the thermal conductor pillar 218b. In alternative to the segments 268a and 268b, the mating elements 250a and/or 250b may be formed from the conductive circuit layers 228 and 230, respectively. Specifically, the mating elements 250a and/or 250b may be formed from segments (not shown) of the respective conductive circuit layers 228 and/or 230 that are bent to define the respective sub-pillars 270a and/or 270b.

When mated together as shown in FIG. 6, the mating elements 250a and 250b are in thermal and electrical contact with each other. The thermal conductor pillar 218b thereby forms both a thermal pathway for heat to travel between the circuit boards 212 and 214 and an electrical pathway between the circuit boards 212 and 214. The mating ends 254 and 258 of the mating elements 250a and 250b may mate together using any geometry, structure, means, connection type, and/or the like. Optionally, the mating end 254 and/or the mating end 258 includes a compliant segment, member, and/or the like that deflects to facilitate separably mating the mating ends 254 and 258 together with a predetermined mating force.

FIG. 7 is an elevational view of another embodiment of a circuit board assembly 310 illustrating another embodiment of thermal conductor pillars 318. The circuit board assembly 310 includes circuit boards 312 and 314, one or more electronic devices 316, and the thermal conductor pillars 318. In the exemplary embodiment of the circuit board assembly 310, the circuit boards 312 and 314 are each ceramic circuit boards that include respective ceramic substrates 320 and 322 and respective conductive circuit layers 328 and 330 positioned on the ceramic substrates 320 and 322. Optionally, the circuit board 312 and/or the circuit board 314 includes a dielectric layer (not shown) that extends between the respective ceramic substrate 320 and/or 322 and the respective conductive circuit layer 328 and/or 330. In the exemplary embodiment of the circuit board assembly 310, the electrical device 316 is mounted to the circuit board 312. In addition or alternatively, one or more electronic devices 316 may be mounted to the circuit board 314. The circuit boards 312 and 314 include conductive circuit layers 328 and 330. Each of the circuit boards 312 and 314 may be referred to herein as a “first” and/or a “second” circuit board. The thermal conductor pillars 318 may be referred to herein as “conductor pillars”.

The thermal pillars 318 include a thermal pillar 318a that is formed from a segment 368 that is a discrete component from the conductive circuit layers 328 and 330. An end 334 of the segment 368 is mounted to the conductive circuit layer 330 such that the segment 368 is mechanically connected to the conductive circuit layer 330 using a component 355 that is discrete from, and engaged with (i.e., physically contacts), both the end 334 and the conductive circuit layer 330. In other words, the end 334 and the conductive circuit layer 330 are more than merely engaged with each other. In the exemplary embodiment of the circuit board assembly 310, the end 334 is mechanically connected to the conductive circuit layer 330 in thermal and electrical contact therewith. The discrete component 355 that mechanically connects the end 334 to the conductive circuit layer 330 is solder in the exemplary embodiment of the circuit board assembly 310. But, the end 334 of the segment 368 may be mechanically connected to the conductive circuit layers 330 using any other discrete component, such as, but not limited to, an epoxy, an adhesive, a press-fit, a collar, a clamp, a threaded fastener, a clip, and/or the like. The end 334 may be referred to herein as a “first” and/or a “second” end.

The segment 368 is bent to define a sub-pillar 370 of the thermal conductor pillar 318a. The sub-pillar 370 includes an end 332 of the thermal conductor pillar 318a that is opposite the end 334. Instead of being mechanically connected to the conductive circuit layer 328 using a discrete component, in the exemplary embodiment of the circuit board assembly 310, the end 332 is configured to separably mate with the conductive circuit layer 328 via engagement (i.e., physical contact) with the conductive circuit layer 328. In the exemplary embodiment of the circuit board assembly 310, the end 332 mates with the conductive circuit layer 328 in thermal and electrical contact therewith. In addition or alternative to the end 334 being mechanically connected to the conductive circuit layer 330 using the discrete component 355, the end 332 may be mechanically connected to the conductive circuit layer 328 using a component (not shown) that is discrete from, and engaged with, the end 332 and the conductive circuit layer 328, such as, but not limited to, solder, an epoxy, an adhesive, a press-fit, a collar, a clamp, a threaded fastener, a clip, and/or the like. The end 332 may be referred to herein as a “first” and/or a “second” end.

In alternative to the segment 368, the thermal conductor pillar 318a may be formed from one of the conductive circuit layers 328 or 330. Specifically, the thermal conductor pillar 318a may be formed from a segment (not shown) of the conductive circuit layer 328 or 330 that is bent to define the sub-pillar 370.

The thermal pillars 318 also include a thermal conductor pillar 318b. The thermal conductor pillar 318b includes a base 372 having an end 374 that, in the exemplary embodiment of the circuit board assembly 310, is mounted to the conductive circuit layer 330 in thermal and electrical contact therewith. A lip 376 extends from the base 372 and includes an end 378 of the thermal conductor pillar 318b that is opposite the end 374. In the exemplary embodiment of the circuit board assembly 310, the end 378 is mounted to the conductive circuit layer 328 in thermal and electrical contact therewith. Optionally, the ends 374 and/or 378 are mechanically connected to the respective conductive circuit layer 330 and/or 328 using respective discrete components 355 and 353. The discrete components 353 and 355 may each be any means, structure, fastener, and/or the like, such as, but not limited to, solder, an epoxy, an adhesive, a press-fit, a collar, a clamp, a threaded fastener, a clip, and/or the like. The ends 374 and 378 may each be referred to herein as a “first” and/or a “second” end.

The lip 376 may be a single structure, for example that extends continuously around the perimeter of the thermal conductor pillar 318b, or the lip 376 may be formed from two or more discrete segments (e.g., from two or more arms that extend from the base 372).

As can be seen in FIG. 7, the lip 376 of the thermal conductor pillar 318b extends around the electronic device 316. In other words, the lip 376 defines an opening 380 of the end 378 of the thermal conductor pillar 318b that receives the electronic device 316 therein. The lip 376 thereby accommodates the location of the electronic device 316 on the circuit board 312 such that the thermal conductor pillar 318b does not interfere with the selected location of the electronic device 316 on the circuit board 312. Moreover, the lip 376 may dissipate heat from around one or more sides (i.e. around all or one or more segments of the perimeter) of the electronic device 316. The lip 376 may facilitate dissipating heat from two or more different locations along the circuit board 312.

FIG. 8 is a schematic diagram of another embodiment of a circuit board assembly 410 illustrating another embodiment of thermal conductor pillars 418. The circuit board assembly 410 includes circuit boards 412 and 414, one or more electronic devices (not shown) mounted to the circuit boards 412 and/or 414, and the thermal conductor pillars 418. In the exemplary embodiment of the circuit board assembly 410, the circuit boards 412 and 414 are each metal core circuit boards that include respective metal substrates 420 and 422, respective dielectric layers 424 and 426 positioned on the metal substrates 420 and 422, and respective conductive circuit layers 428 and 430 positioned on the metal substrates 420 and 422. In the exemplary embodiment of the circuit board assembly 410, the dielectric layers 424 and 426 are positioned directly on the metal substrates 420 and 422, respectively, and the conductive circuit layers 428 and 430 are positioned directly on the dielectric layers 424 and 426, respectively. The circuit boards 412 and 414 are arranged such that the conductive circuit layers 428 and 430 face each other across a gap. Each of the circuit boards 412 and 414 may be referred to herein as a “first” and/or a “second” circuit board. The thermal conductor pillars 418 may be referred to herein as “conductor pillars”.

The thermal conductor pillars 418 are not mechanically connected to the conductive circuit layers 428 and 430 using discrete components. Rather, in the exemplary embodiment of the circuit board assembly 410, the thermal conductor pillars 418 are merely engaged with the conductive circuit layers 428 and 430. Specifically, each thermal conductor pillar 418 includes an end 432 that is engaged with (i.e., physically contacts) the conductive circuit layer 428. Each thermal conductor pillar 418 includes an opposite end 434 that is engaged with the conductive circuit layer 430. The circuit board assembly 410 includes fasteners 482 that mechanically connect the circuit boards 412 and 414 together such that the thermal conductor pillars 418 are engaged between the circuit board 412 and 414. In the exemplary embodiment of the circuit board assembly 410, the thermal conductor pillars 418 are engaged with the conductive circuit layers 428 and 430 in thermal and electrical contact therewith. The pressure applied to the ends 432 and 434 of the thermal conductor pillars 418 by the respective circuit boards 412 and 414 holds the thermal conductor pillars 418 between the circuit boards 412 and 414. The fasteners 482 can be adjusted such that the circuit boards 412 and 414 apply a sufficient amount of pressure to hold the thermal conductor pillars 418 between the circuit boards 412 and 414 without collapsing or otherwise damaging the pillars 418. It should be understood that the pressure applied by the fasteners 482 to hold the thermal conductor pillars 418 between the circuit boards 412 and 414 without collapsing or otherwise damaging the thermal conductor pillars 418 may compress the thermal conductor pillars 418. The pressure provided by the fasteners 482 may facilitate establishing a predetermined contact force between the ends 432 and 434 and the respective conductive circuit layers 428 and 430, which may facilitate providing a predetermined thermal and/or electrical interface between the ends 432 and 434 and the respective conductive circuit layers 428 and 430. The ends 432 and 434 may each be referred to herein as a “first” and/or a “second” end.

The lengths of the thermal conductor pillars 418 may be selected to provide the gap between the conductive circuit layers 428 and 430 with a predetermined dimension. For example, the lengths of the thermal conductor pillars 418 may be selected to facilitate ensuring that the gap has a predetermined minimum dimension.

In the exemplary embodiment of the circuit board assembly 410, both of the ends 432 and 434 of the thermal conductor pillars 418 are merely engaged with (i.e., physically contacts) the respective conductive circuit layer 428 and 430. Alternatively, one of the ends 432 or 434 of one or more of the thermal conductor pillars 418 is mechanically connected to the respective conductive circuit layer 428 or 430 using a component (not show) that is discrete from, and engaged with (i.e., physically contacts), the end 432 or 434 and the respective conductive circuit layer 428 or 430, such as, but not limited to, solder, an epoxy, an adhesive, a press-fit, a collar, a clamp, a threaded fastener, a clip, and/or the like. Although the fasteners 482 are shown as threaded fasteners, the circuit board assembly 410 is not limited thereto. Rather, the circuit boards 412 and 414 may be mechanically connected together using any other any suitable method, means, structure, fastener, and/or the like, such as, but not limited to, a collar, an elastic member (e.g., an elastic band), a clamp, a clip, and/or the like.

Optionally, one or more of the fasteners 482 is configured to conduct heat in a substantially similar manner to the thermal conductor pillars 418. For example, one or more of the fasteners 482 may have a relatively low thermal resistance and a relatively high thermal conductivity. Examples of a relatively high thermal conductivity k of the fasteners 482 include, but are not limited to, greater than approximately 100 W/(m·K), greater than approximately 200 W/(m·K), greater than approximately 300 W/(m·K), and/or the like. As can be seen in FIG. 8, each fastener 482 is engaged with (i.e., physically contacts) both of the metal substrates 420 and 422 at opposite ends of the fastener 482. One or more of the fasteners 482 may thus define a thermal conductor pillar that provides a thermal pathway for heat to travel directly between the metal substrates 420 and 422. The fasteners 482 may each be referred to herein as a “thermal conductor pillar”.

Moreover, one or more of the fasteners 482 is optionally electrically conductive such that the fastener 482 defines an electrical pathway directly between the metal substrates 420 and 422. For example, in the exemplary embodiment of the circuit board assembly 410, the fasteners 482 are each electrically conductive. In such embodiments wherein a fastener 482 is electrically conductive, the pattern of the conductive circuit layers 428 and 430 is selected such that the electrically conductive fastener 482 does not electrically connect to the conductive circuit layers 428 and 430, for example as is shown with the fasteners 482 in FIG. 8.

FIG. 9 is a cross-sectional view of another embodiment of a circuit board assembly 510 illustrating more than two circuit boards arranged in a stack. The circuit board assembly 510 includes three circuit boards 512, 514, and 584 arranged in a stack. The circuit board assembly 510 also includes thermal conductor pillars 518 and one or more electronic devices (not shown) mounted to the circuit boards 512, 514, and/or 584. The circuit boards 512 and 514 include respective substrates 520 and 522 and respective conductive circuit layers 528 and 530 positioned on the substrates 520 and 522. The circuit board 584 includes a substrate 586 and opposite conductive circuit layers 588 and 590. In the exemplary embodiment of the circuit board assembly 510, the substrates 520, 522, and 586 are each fabricated from a composite material, such as, but not limited to, epoxy glass, FR4, and/or the like). In some embodiments, one or more of the circuit boards 512, 514, and/or 584 is a different type of circuit board as compared to one or more of the other circuit boards 512, 514, and/or 584. Each of the circuit boards 512, 514, and 584 may be referred to herein as a “first” and/or a “second” circuit board. The thermal conductor pillars 518 may be referred to herein as “conductor pillars”.

In the exemplary embodiment of the circuit board assembly 510, the thermal conductor pillars 518 include one or more thermal conductor pillars 518a that extend between the circuit boards 512 and 584, one or more thermal conductor pillars 518b that extend between the circuit boards 514 and 584, and one or more thermal conductor pillars 518c that extend between the circuit boards 512 and 514. Specifically, opposite ends 532a and 534a of the thermal conductor pillars 518a are engaged in thermal and electrical contact with the respective conductive circuit layers 528 and 588 of the respective circuit boards 512 and 584. The thermal conductor pillars 518a thus provide thermal and electrical pathways between the circuit boards 512 and 584. In the exemplary embodiment of the circuit board assembly 510, opposite ends 532b and 534b of the thermal conductor pillars 518b are engaged in thermal and electrical contact with the respective conductive circuit layers 530 and 590 of the respective circuit boards 514 and 584. Accordingly, the thermal conductor pillars 518b provide thermal and electrical pathways between the circuit boards 514 and 584. In the exemplary embodiment of the circuit board assembly 510, opposite ends 532c and 534c of the thermal conductor pillars 518c are engaged in thermal and electrical contact with the respective conductive circuit layers 528 and 530 of the respective circuit boards 512 and 514, thus providing thermal and electrical pathways between the circuit boards 512 and 514. Each of the ends 532a, 532b, 532c, 534a, 534b, and 534c may each be referred to herein as a “first” and/or a “second” end.

Each of the circuit boards 512, 514, and 584 may include any number of electronic devices mounted thereto. For example, one or more of the circuit boards 512, 514, and/or 584 may not include any electronic devices mounted thereto. In some embodiments, and for example, the circuit board 584 includes one or more electronic devices mounted to the conductive circuit layer 588 and/or one or more electronic devices mounted to the conductive circuit layer 590. Moreover, in some embodiments, the circuit board 584 is a control board that controls one or more electronic devices mounted to the circuit board 512 and/or that controls one or more electronic device mounted to the circuit board 514, whether or not the circuit board 584 includes any electronic devices mounted thereto.

Optionally, the circuit board 512 and/or the circuit board 514 is mounted, whether directly or indirectly, to a respective heat sink 546 and 548. In the exemplary embodiment of the circuit board assembly 510, the circuit boards 512 and 514 are directly mounted to the respective heat sinks 546 and 548. But, in other embodiments that the heat sink 546 and/or the heat sink 548 may be a remote heat sink that is thermally connected to the respective substrate 520 and 522 via one or more saddles (not shown), one or more heat pipes (not shown), and/or the like. Moreover, in addition or alternatively to the heat sink 546 and/or the heat sink 548, the substrates 520 and/or 522 may be mounted, whether directly or indirectly, to another type of heat reservoir, such as, but not limited to, a cooling plate, a liquid tank and/or other container, and/or the like.

Although three are shown, the circuit board assembly 510 may include any number of circuit boards. For example, in applications wherein the circuit board assembly 510 is used to control three phase electrical power, the assembly 10 may include a stack of three circuit boards that each holds one or more electronic devices, with a fourth circuit board (which may or may not be arranged in the stack) that is a control board that controls the electronic devices of the three other circuit boards.

Although the circuit board 584 is shown as being arranged in the stack with the circuit boards 512 and 514, in other embodiments the circuit board 584 may be arranged approximately coplanar with the circuit board 512 or with the circuit board 514. Moreover, in some embodiments wherein the circuit board 584 is not arranged in the stack, the circuit board 584 may include thermal conductor columns 518 and/or may be a metal core circuit board such that the circuit board 584 and the circuit board 512 or 514 with which the circuit board 584 is approximately coplanar provide independent cooling for two zones.

FIG. 10 is a schematic diagram of another embodiment of a circuit board assembly 610. The circuit board assembly 610 includes circuit boards 612 and 614, one or more electronic devices 616 mounted to the circuit board 612 and/or the circuit board 614, thermal conductor pillars 618, and a heat conducting material 619. The circuit boards 612 and 614 include respective substrates 620 and 622 and respective conductive circuit layers 628 and 630 positioned on the substrates 620 and 622. In the exemplary embodiment of the circuit board assembly 610, a single electronic device 616 is mounted on the conductive circuit layer 628 of the circuit board 612 in electrical connection with the conductive circuit layer 628. Each of the circuit boards 612 and 614 may be referred to herein as a “first” and/or a “second” circuit board. The thermal conductor pillars 618 may be referred to herein as “conductor pillars”.

The circuit boards 612 and 614 are arranged such that the conductive circuit layers 628 and 630 face each other across a gap G₁. Specifically, the thermal conductor pillars 618 extend lengths between the conductive circuit layers 628 and 630 such that the thermal conductor pillars 618 space the conductive circuit layers 628 and 630 apart by the gap G₁. The lengths of the thermal conductor pillars 618 may be selected to provide the gap G₁ with a predetermined dimension, for example to provide a predetermined amount of space between the circuit boards 612 and 614.

The heat conducting material 619 is positioned between the circuit boards 612 and 614 such that the heat conducting material 619 fills the gap G₁ between the conductive circuit layers 628 and 630 along at least a portion of the lengths and/or widths of the circuit boards 612 and 614. The heat conducting material 619 is engaged with both of the conductive circuit layers 628 and 630 in thermal contact therewith. The heat conducting material 619 is fabricated from one or more dielectric materials such that the heat conducting material 619 is electrically insulating. The heat conducting material 619 electrically isolates the conductive circuit layers 628 and 630 from each other.

The heat conducting material 619 is configured to conduct heat. Specifically, the heat conducting material 619 has a relatively low thermal resistance and a relatively high thermal conductivity. Examples of a relatively high thermal conductivity k of the heat conducting material 619 include, but are not limited to, greater than approximately 5 W/(m·K), greater than approximately 9 W/(m·K), and/or the like. The heat conducting material 619 may be fabricated from any materials that enable the heat conducting material 619 to function as described and/or illustrated herein, such as, but not limited to, an epoxy, a thermal conductor filler material, a material having metal particles embedded therein, and/or the like. The size (e.g., length, diameter, width, thickness, and/or the like), shape, and/or the material of the heat conducting material 619 may be selected to affect the thermal conductivity and/or thermal resistivity properties of the heat conducting material 619. The heat conducting material 619 may be fabricated from any materials, may have any size, and may have any shape, which may be selected to provide the heat conducting material 619.

The heat conducting material 619 provides a thermal pathway for heat to travel between the circuit boards 612 and 614. The heat conducting material 619 is configured to dissipate heat from the electronic device 616 via the thermal pathways between the circuit boards 612 and 614. Specifically, in the exemplary embodiment of the circuit board assembly 610, heat generated from the electronic device 616 is conducted both directly to the heat conducting material 619 and through the circuit board 612. Some of the heat conducted through the circuit board 612 and some of the heat received by the heat conducting material 619 directly from the electronic device 616 travels through the conductive circuit layer 628 and through the substrate 620, for example for dissipation directly to the environment and/or to a heat sink (not shown) mounted to the substrate 620. Moreover, some of the heat conducted through the circuit board 612 travels through the conductive circuit layer 628 to the heat conducting material 619. The heat conducting material 619 conducts the heat received from the conductive circuit layer 628 and some of the heat received directly from the electronic device 616 along the gap G₁ to the conductive circuit layer 630 of the circuit board 614. The heat travels through the conductive circuit layer 630 and through the substrate 622, for example for dissipation directly to the environment and/or to a heat sink (not shown) mounted to the substrate 622. The heat conducting material 619 can thereby be used to passivate the electronic device 616 while performing the thermal function of spreading heat. In embodiments wherein the heat conducting material 619 is fabricated from a material having conductive particles embedded therein, the electrical component 616 may be passivated to prevent electrical shorting.

As described above, the thermal conductor pillars 618 space the conductive circuit layers 628 and 630 of the respective circuit boards 612 and 614 apart by the gap G₁. Optionally, the thermal conductor pillars 618 provide thermal pathways for heat to travel between the circuit boards 612 and 614 and/or provide electrical pathways between the conductive circuit layers 628 and 630.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope. Dimensions, types of materials, orientations of the various components, and the number and positions of the various components described herein are intended to define parameters of certain embodiments, and are by no means limiting and are merely exemplary embodiments. Many other embodiments and modifications within the spirit and scope of the claims will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means-plus-function format and are not intended to be interpreted based on 35 U.S.C. §112, sixth paragraph, unless and until such claim limitations expressly use the phrase “means for” followed by a statement of function void of further structure.

What is claimed is:

1. A circuit board assembly comprising:
first and second circuit boards each comprising a substrate and a conductive circuit layer positioned on the substrate, the first and second circuit boards being arranged such that the conductive circuit layers face each other across a gap; and
thermal conductor pillars extending lengths across the gap between the conductive circuit layers of the first and second circuit boards, the thermal conductor pillars comprising opposite first and second ends that are engaged in thermal contact with the conductive circuit layers of the first and second circuit boards, respectively, wherein the thermal conductor pillars provide thermal pathways for heat to travel between the first and second circuit boards.

2. The circuit board assembly of claim 1, further comprising an electronic device mounted on the conductive circuit layer of the first circuit board in electrical connection therewith, the thermal conductor pillars being configured to dissipate heat from the electronic device via the thermal pathways between the first and second circuit boards.

3. The circuit board assembly of claim 1, further comprising an electronic device mounted on the conductive circuit layer of the first circuit board in electrical connection therewith, wherein heat from the electronic device is configured to flow from the electronic device, along the conductive circuit layer of the first circuit board, along the thermal conductor pillars to the conductive circuit layer of the second circuit board, and along the conductive circuit layer of the second circuit board to the substrate of the second circuit board.

4. The circuit board assembly of claim 1, wherein the thermal conductor pillars are electrically conductive, the first and second ends of the thermal conductor pillars being engaged in electrically contact with the conductive circuit layers of the first and second circuit boards, respectively, the thermal conductor pillars providing an electrical connection between the conductive circuit layers of the first and second circuit boards.

5. The circuit board assembly of claim 1, wherein the thermal conductor pillars provide a mechanical connection between the conductive circuit layers of the first and second circuit boards.

6. The circuit board assembly of claim 1, wherein the thermal conductor pillars comprise metal.

7. The circuit board assembly of claim 1, wherein the thermal conductor pillars comprise thermal conductivities k of greater than approximately 100 W/(m·K).

8. The circuit board assembly of claim 1, wherein the substrate of at least one of the first circuit board or the second circuit board is a metal substrate, a ceramic substrate, a direct bond copper substrate, or a composite substrate.

9. The circuit board assembly of claim 1, wherein the thermal conductor pillars comprise at least one of a cylindrical shape, a non-cylindrical shape, a sinewy shape, a bent shape, a plus shape, a cross shape, a wavy corrugation shape, an H-shape, an elongated rectangular shape, a honeycomb shape, a rectangular cross-sectional shape, a square cross-sectional shape, a triangular cross-sectional shape, or an oval cross-sectional shape.

10. The circuit board assembly of claim 1, wherein the substrate of at least one of the first or second circuit boards is mounted directly or indirectly to a heat sink.

11. The circuit board assembly of claim 1, wherein the conductive circuit layer of at least one of the first or second circuit boards comprises at least one of a contact pad or a trace.

12. The circuit board assembly of claim 1, wherein the substrates of the first and second circuit boards are metal substrates, at least one of the thermal conductor pillars being engaged with the metal substrate of both the first circuit board and the second circuit board.

13. A circuit board assembly comprising:
first and second circuit boards each comprising a substrate and a conductive circuit layer positioned on the substrate, the first and second circuit boards being arranged such that the conductive circuit layers face each other across a gap;
an electronic device mounted on the conductive circuit layer of the first circuit board in electrical connection therewith; and
conductor pillars extending lengths across the gap between the conductive circuit layers of the first and second circuit boards, the conductor pillars being electrically conductive, the conductor pillars comprising opposite first and second ends that are engaged in electrical contact with the conductive circuit layers of the first and second circuit boards, respectively, the conductor pillars providing an electrical connection between the conductive circuit layers of the first and second circuit boards.

14. The circuit board assembly of claim 13, wherein the first and second ends of the conductor pillars are engaged in thermal contact with the conductor circuit layers of the first and second circuit boards, respectively, the conductor pillars providing thermal pathways for heat to travel between the first and second circuit boards, the thermal conductor pillars being configured to dissipate heat from the electronic device via the thermal pathways between the first and second circuit boards.

15. The circuit board assembly of claim 13, wherein the conductor pillars provide a mechanical connection between the conductive circuit layers of the first and second circuit boards.

16. The circuit board assembly of claim 13, wherein the electronic device comprises at least one of an active electronic device, a passive electronic device, a diode, a resistor, a switch, a relay, a transistor, a semiconductor, a semiconductor switch, a power diode, or a power resistor.

17. The circuit board assembly of claim 13, wherein the substrate of at least one of the first circuit board or the second circuit board is a metal substrate, a ceramic substrate, a direct bond copper substrate, or a composite substrate.

18. The circuit board assembly of claim 13, wherein the substrate of at least one of the first or second circuit boards is mounted directly or indirectly to a heat sink.

19. The circuit board assembly of claim 13, wherein the conductive circuit layer of at least one of the first or second circuit boards comprises at least one of a contact pad, a wire bond, a via, or a trace.

20. A circuit board assembly comprising:
first and second circuit boards each comprising a substrate and a conductive circuit layer positioned on the substrate, the first and second circuit boards being arranged such that the conductive circuit layers face each other across a gap; a semiconductor switch mounted on the conductive circuit layer of the first circuit board in electrical connection therewith, the semiconductor switch being configured to switch circuit branches on and off; and
conductor pillars extending lengths across the gap between the conductive circuit layers of the first and second circuit boards, the conductor pillars comprising opposite first and second ends that are engaged in at least one of thermal or electrical contact with the conductive circuit layers of the first and second circuit boards, respectively, the conductor pillars providing at least one of thermal pathways for heat to travel between the first and second circuit boards or an electrical connection between the conductive circuit layers of the first and second circuit boards.
